(19) United States
(12) Patent Application Publication
(10) Pub. No.: US 2011/0068410 A1
(43) Pub. Date: Mar. 24, 2011

(54) SILICON DIE FLOORPLAN WITH APPLICATION TO HIGH-VOLTAGE FIELD EFFECT TRANSISTORS

(76) Inventors: Martin E. Garnett, Los Gatos, CA (US); Michael R. Hsing, Saratoga, CA (US)

(21) Appl. No.: 12/750,248

(22) Filed: Mar. 30, 2010

Related U.S. Application Data
(63) Continuation-in-part of application No. 12/562,328, filed on Sep. 18, 2009.

(51) Int. Cl. H01L 27/06

(52) U.S. Cl. 257/379; 257/E27.016

(57) ABSTRACT

A floorplan for a die having three high-voltage transistors for power applications is described. The three high-voltage transistors are specifically placed in relation to each other to optimize operation.

### CROSS REFERENCE TO RELATED APPLICATIONS

This application is a continuation-in-part of and claims the benefit of application U.S. patent application Ser. No. 12/562,328, filed Sep. 18, 2009 and titled HIGH VOLTAGE JUNCTION FIELD EFFECT TRANSISTOR WITH SPIRAL FIELD PLATE, which is incorporated herein by reference in its entirety.

### TECHNICAL FIELD

The present invention relates to a semiconductor floorplan for high voltage field effect transistors.

### BACKGROUND

In some power electronic applications, an integrated package and die size may be chosen to satisfy cost or compatibility requirements, in which case there is a need to optimize the placement and size of high-voltage transistors on the die to meet the breakdown voltage and current handling requirement of the transistors, subject to the constraint of the die size.

### BRIEF DESCRIPTION OF THE DRAWINGS

FIG. 1 illustrates the floorplan of a die according to an embodiment of the disclosed invention.

FIGS. 2 and 3 illustrate a lateral MOSFET as an example of the lateral MOSFET in the embodiment of FIG. 1.

### DETAILED DESCRIPTION

In the description that follows, the scope of the term “some embodiments” is not to be so limited as to mean more than one embodiment, but rather, the scope may include one embodiment, more than one embodiment, or perhaps all embodiments.

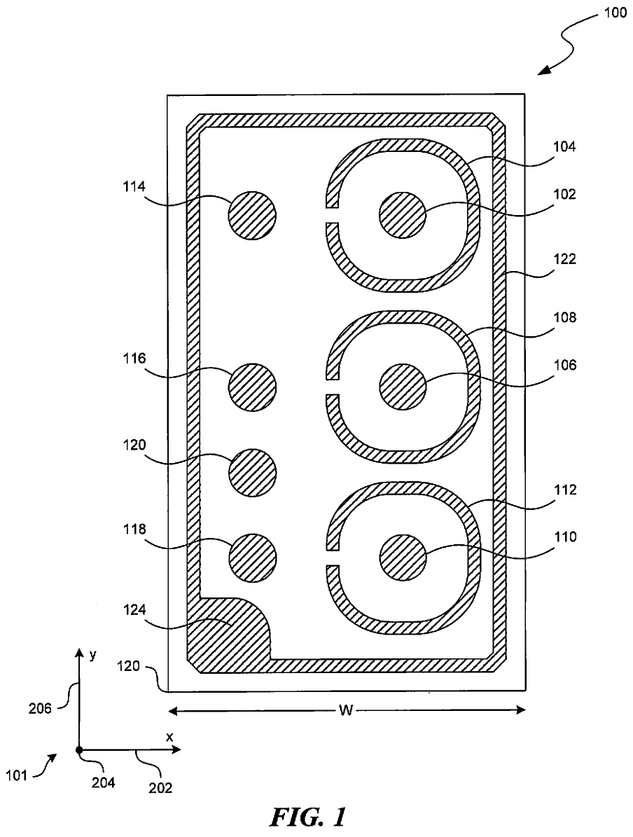

FIG. 1 illustrates a layout, or floorplan, of die 100 according to an embodiment, where integrated on die 100 are three lateral MOSFETs (Metal Oxide Semiconductor Field Effect Transistor). Each MOSFET has the same dimensions and layout. Drain pad 102 and source 104 form part of a first MOSFET, drain pad 106 and source 108 form part of a second MOSFET, and drain pad 110 and source 112 form part of a third MOSFET. Source pad 114 is electrically connected to source 104 and serves as a pad for source 104, source pad 116 is electrically connected to source 108 and serves as a pad for source 108, and source pad 118 is electrically connected to source 112 and serves as a pad for source 112. The metallization layers connecting the source pads to their respective sources are not shown for ease of illustration.

The three MOSFETs share a common gate pad 120. The metallization layer connecting gate pad 120 to the gates of each of the MOSFETs is not shown for ease of illustration. Metal layer 122 is connected to the substrate body of the MOSFETs, where pad 124 serves as a ground pad.

The layout illustrated in FIG. 1 is optimized to minimize die size, and yet have enough silicon area for integrating three MOSFETs with a given breakdown voltage. For some embodiments, the breakdown voltage may be 740V. Other embodiments may have different values for the transistor breakdown voltage. Coordinate system 101, with x-axis 202 and y-axis 206 shown lying in the plane of the illustration, and with origin 204, serves as a reference for describing the placement of the MOSFETs. Corner 120 may be considered as coinciding with origin 204, where the long dimension of die 100 is co-linear with y-axis 206, and the short dimension of die 100 is co-linear with x-axis 202. For ease of illustration, corner 102 is shown as being displaced from origin 204.

Relative to origin 204, or equivalently corner 120, the centers of drain pads 102, 106, and 110 may be given relative to a scale. The scale chosen is the width of die 100, denoted by W in FIG. 1. Accordingly, for the embodiment of FIG. 1, the positions of the centers of drains 102, 106, and 110 may be described, respectively, by the ordered pairs (x₁W, y₁W), (x₂W, y₂W), and (x₃W, y₃W).

As an example, an embodiment may have a die size of 0.75 mm by 1.41 mm, so that for such an embodiment W=0.75 mm, and may have positions for the center of the drains given by: x₁=0.639, y₁=0.634; x₁=0.639, y₁=0.941; and x₁=0.639, y₁=1.517.

For some embodiments, the tolerance for these drain positions may be written as ±σW. As an example, some embodiments may have a tolerance such that σ is in the range of 0.0033 to 0.0066. Embodiments may have a tolerance with different values. Accordingly, the positions of the centers of drains 102, 106, and 110 may be described, respectively, by the ordered pairs ({x₁±σ}W, {y₁±σ}W), ({x₂±σ}W, {y₂±σ}W), and ({x₃±σ}W, {y₃±σ}W), where the tolerance has been included in the coordinate positions. For example, ({x₁±σ}W, {y₁±σ}W) is to be interpreted to mean that an embodiment may have the center of drain 102 at some coordinate position (xW, yW), where x₁−σ≦x≦x₁+σand y₁−σ≦y≦y₁+σ. Similar statements apply to the other coordinate positions.

Sources 104, 108, and 112 are circular in nature, although they are not necessarily exact circles, but may be linear in some regions. Other embodiments may comprise differently shaped sources. Accordingly, for some embodiments, a substantial portion of a transistor may be viewed as lying within a circle of some radius rW with respect to the center of its drain pad. As an example, an embodiment may have r=0.305. For some embodiments, the tolerance for the radius may be represented as δW. As an example, some embodiments may have δin the range of 0.0033 to 0.0066. Accordingly, reciting that a transistor lies within a radius of (r±δ)W is to be interpreted to mean that a substantial portion of the transistor, e.g., the source of the transistor, lies within a circle having some radius between r−δ and r+δ.

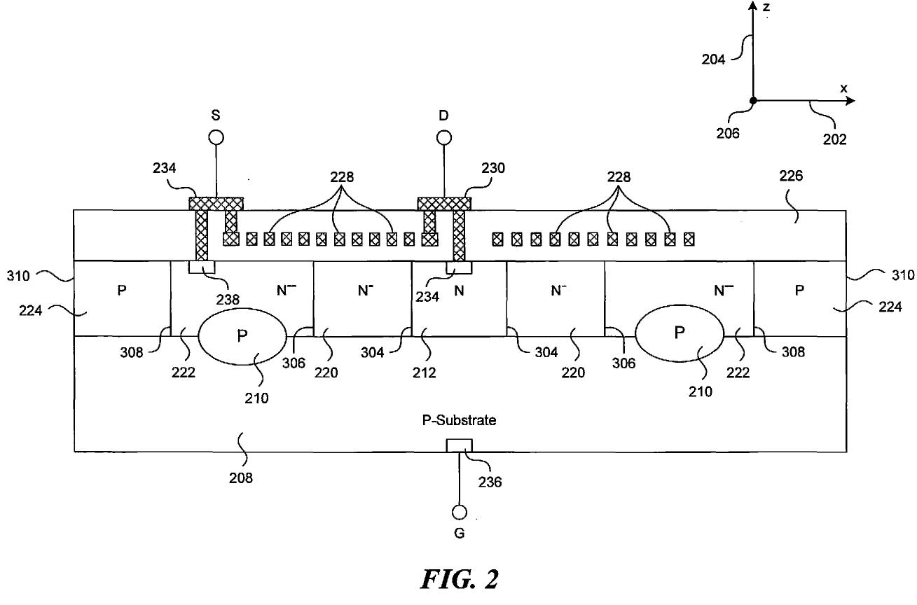

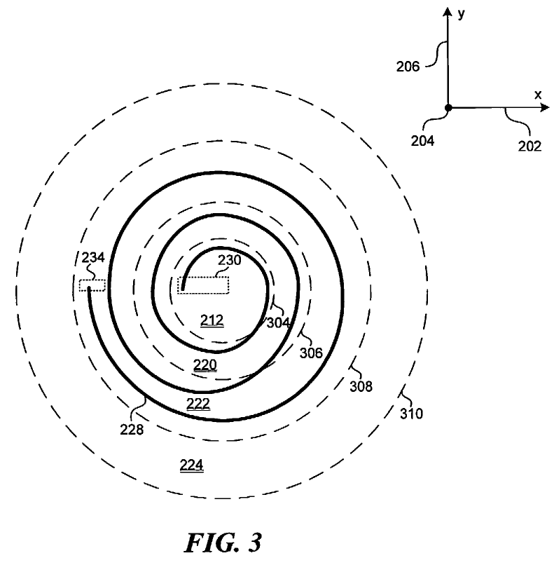

An example of a lateral MOSFET that may be used in the embodiment of FIG. 1 is now described with respect to FIGS. 2 and 3. These figures share the same coordinate system as illustrated in FIG. 1 so that their relative orientations to each other may be clear from the illustrations.

FIG. 2 illustrates a cross-sectional plan view of a portion of a silicon die according to an embodiment. For ease of illustration, FIG. 2 is not drawn to scale, and various doped regions are idealized as rectangles. For reference, shown in FIG. 2 is a coordinate system with x-axis 202 and z-axis 204 lying in the plane of illustration, with y-axis 206 pointing into the plane of the illustration. With the coordinate system as shown, the cross-sectional view illustrated in FIG. 2 is taken as a slice of an embodiment, with the slice perpendicular to y-axis 206.

FIG. 3 illustrates a cross-sectional plan view of a portion of the silicon die according to an embodiment, but with a different view than that of FIG. 2. To provide relative orientations of the embodiment of FIG. 2 and the embodiment of FIG. 3, the coordinate system in FIG. 2 is also shown in FIG. 3, making clear that the cross-sectional view illustrated in FIG. 3 is a slice of an embodiment, with the slice taken perpendicular to z-axis 204. For ease of illustration, FIG. 3 is not drawn to scale.

Referring to FIG. 2, formed in p-doped substrate 208 is p-doped buried layer 210. Regions 212, 220, and 222 are n-doped regions, where regions 220 and 222 appear noncontiguous only because of the way the slice is taken to provide the view of the illustration, but for the embodiments of FIGS. 2 and 3, regions 220 and 222 are contiguous and surrounds n-doped region 212. This is made clear by the view illustrated in FIG. 3, where dashed circles 304 and 306 in FIG. 3 correspond, respectively, to junctions 304 and 306 in FIG. 2, where junction 304 is the junction between n-doped regions 212 and 220, and junction 306 is the junction between n-doped regions 220 and 222.

Adjacent to n-doped region 212 is n-doped region 220 surrounding n-doped region 212, represented by the annulus between dashed circles 304 and 306 in FIG. 3. N-doped region 220 is doped less than n-doped region 212, as indicated by the symbol N⁻in FIG. 2. Adjacent to n-doped region 220 is n-doped region 222 surrounding n-doped region 220, represented by the annulus between dashed circles 306 and 308 in FIG. 3. N-doped region 222 is doped less than n-doped region 220, as indicated by the symbol N⁻in FIG. 2. N-doped region 222 is formed over p-buried layer 210 so that there is an n-p junction formed by their interface. Adjacent to n-doped region 222 is p-doped region 224, represented by the annulus between dashed circles 308 and 310 in FIG. 3. P-doped region 224 may be part of p-substrate 208, but for ease of discussion is labeled as a distinct region. Regions 212, 220, 222, and 224 may not be exactly circular in shape, and for some embodiments, may take on other geometric shapes, or they may be irregular.

Referring to FIG. 2, label 226 denotes a dielectric layer, such as for example SiO₂. Formed in oxide layer 226 is spiral resistor 228. Spiral resistor 228 may also be referred to as a spiral field plate. In FIG. 2, the cross-sectional view of spiral resistor 228 is indicated by the hatched rectangles. Solid spiral line 228 in FIG. 3 represents spiral resistor 228, however, a simplification is made because the number of turns of spiral resistor 228 as shown in FIG. 3 is less than the number of turns represented in FIG. 2. Also, for simplicity all turns in FIG. 3 are shown equal in thickness (in the x-y plane), whereas this is not so for FIG. 2. Furthermore, for clarity of illustration, the scale of the various regions in FIG. 3 does not match that of FIG. 2. The slice in FIG. 3 is taken along spiral resistor 228 in the x-y plane, hence other structures in FIG. 3 are shown dashed because they are present below or above (along the z-axis dimension) the slice.

The inner end of spiral resistor 228 is electrically connected to n-doped region 212. For example, in embodiments represented by the illustrations in FIGS. 2 and 3, the inner most end of spiral resistor 228 is connected to n-doped region 212 by way of highly doped n-region 234, and by a set of vias and an interconnect, collectively labeled by the numeral 230, and shown cross-hatched in the illustration of FIG. 2 and as a dashed rectangle in FIG. 3. Region 234 is a highly doped n-region to provide a good electrical contact between spiral resistor 228 and region 212, so that highly doped n-region 234 and set of vias and interconnect 230 serve as an ohmic contact.

The outer end of spiral resistor 228 is electrically connected to n-doped region 222. For example, in embodiments represented by the illustrations in FIGS. 2 and 3, the outer most end of spiral resistor 228 is connected to n-doped region 222 by way of highly doped n-region 238, and by a set of vias and an interconnect, collectively labeled by the numeral 234, and shown cross-hatched in the illustration of FIG. 2 and as a dashed rectangle in FIG. 3. Region 238 is highly doped to provide a good electrical contact between spiral resistor 228 and region 222, so that highly doped n-region 238 and set of vias and interconnect 234 serve as an ohmic contact.

Spiral resistor 228 may not be exactly a spiral, and for some embodiments spiral resistor 228 may not have a spiral shape, but instead may meander from above region 212 to above region 222. Some embodiments may have spiral resistor 228 comprising straight sections, so as to enclose a region somewhat rectangular in nature, but with curved corners. Accordingly, in general, the descriptive term “spiral resistor” is not meant to imply that the resistor coupling the outer n-doped region (e.g., 222) to the inner n-doped region (e.g., 212) is necessarily spiral in shape.

For some embodiments, spiral resistor 228 may comprise polysilicon. Well known design techniques may be used so that spiral resistor 228 has some desired resistance. For example, for some embodiments the sheet resistance of the polysilicon used for spiral resistor 228 may be from 1KΩ/square to 5KΩ/square, and a typical resistance for spiral resistor 228 may be in the neighborhood of 60 MΩ. For some embodiments, the typical radii of curvature for the bends in spiral resistor 228 may be in the neighborhood of 100 μm to 200 μm. These numerical values are given merely to provide examples. Other embodiments may have numerical values not represented by these numerical ranges or values.

Regions 212, 220, and 222 provide a graded doping profile. For simplicity, only three such graduations or steps in doping are shown, but other embodiments may have a different number of such graduations or steps in doping level. As an example of doping levels, region 212 may have a doping level in the range of 10¹⁵cm⁻³ to 10¹⁶cm⁻³, where the doping profile is such that region 220 is doped at 1/10 the level of region 212, and region 222 is doped at 1/10 the level of region 220. These numerical values are given merely to provide examples. Other embodiments may have numerical values not represented by these numerical ranges or values.

The integrated device illustrated in FIG. 2 comprises an nJFET, where interconnect 230 serves as the drain (labeled “D”), interconnect 234 serves as the source (labeled “S”), and p-substrate 208 serves as the gate (labeled “G”), where highly doped p-region 236 provides an ohmic contact for the gate. In practice, the drain may be at some relatively high voltage, such as the supply voltage V_{IN}, and the gate may be grounded, where it is desired that the source voltage not rise too high, such as for example in the range of a few tens of volts.

The drain-source voltage difference appears across spiral resistor 228, but if the resistance of spiral resistor 228 is sufficiently high, the resulting current may be set to a relatively low value to reduce wasted power and heat. Spiral resistor 228 sets the voltage potential at the surfaces of regions 212, 220, and 222, so as to mitigate high electric fields that may cause breakdown. The graded doping profile provided by regions 212, 220, and 222 profiles the depletion region between p-substrate 208 and n-doped regions 212, 220, 222 so that the depletion region has less depth towards p-doped region 224, thereby mitigating punch-through.

Various modifications may be made to the described embodiments without departing from the scope of the invention as claimed below.

I/we claim:

1. A die having a width W and a corner, the die comprising:
a first transistor comprising a drain having a center at a coordinate position ({0.639±σ}W, {0.634±σW}) relative to the corner;
a first transistor comprising a drain having a center at a coordinate position ({0.639±σ}W, {0.941±σW}) relative to the corner; and
a first transistor comprising a drain having a center at a coordinate position ({0.639±σ}W, {1.517±σW}) relative to the corner;
wherein 0<σ<0.01.

2. The die as set forth in claim 1, wherein σ<0.007.

3. The die as set forth in claim 1, wherein σ<0.004.

4. The die as set forth in claim 1, wherein the die has a size of 0.75 mm by 1.41 mm, wherein W=0.75 mm.

5. The die as set forth in claim 1,
wherein the first transistor comprises a source lying within a radius (r±δ)W with respect to the center of the drain of the first transistor;
wherein the second transistor comprises a source lying within a radius (r±δ)W with respect to the center of the drain of the second transistor; and
wherein the third transistor comprises a source lying within a radius (r±δ)W with respect to the center of the drain of the third transistor;
wherein r=0.305 and 0<δ<0.01.

6. The die as set forth in claim 5, wherein δ<0.007.

7. The die as set forth in claim 5, wherein δ<0.004.

8. The die as set forth in claim 1, the die further comprising a substrate;
the first transistor comprising:
a p-doped buried layer adjacent to the substrate;
an n-doped region adjacent to the p-doped buried layer and the substrate, the n-doped region comprising a first n-doped region having a first doping concentration, and a last n-doped region adjacent to the p-doped buried layer and having a last doping concentration less than the first doping concentration; and
a resistor electrically coupled to the first n-doped region and to the last n-doped region.

9. The die as set forth in claim 8,
the second transistor comprising:
a p-doped buried layer adjacent to the substrate;
an n-doped region adjacent to the p-doped buried layer of the second transistor and the substrate, the n-doped region of the second transistor comprising a first n-doped region having a first doping concentration, and a last n-doped region adjacent to the p-doped buried layer of the second transistor and having a last doping concentration less than the first doping concentration of the second transistor; and
a resistor electrically coupled to the first n-doped region of the second transistor and to the last n-doped region of the second transistor; and
the third transistor comprising:
a p-doped buried layer adjacent to the substrate;
an n-doped region adjacent to the p-doped buried layer of the third transistor and the substrate, the n-doped region of the third transistor comprising a first n-doped region having a first doping concentration, and a last n-doped region adjacent to the p-doped buried layer of the third transistor and having a last doping concentration less than the first doping concentration of the third transistor; and
a resistor electrically coupled to the first n-doped region of the third transistor and to the last n-doped region of the third transistor.

10. The die as set forth in claim 9,
wherein the resistor of the first transistor lies within a radius (r±δ)W with respect to the center of the drain of the first transistor;
wherein the resistor of the second transistor lies within a radius (r±δ)W with respect to the center of the drain of the second transistor; and
wherein the resistor of the third transistor lies within a radius (r±δ)W with respect to the center of the drain of the third transistor;
wherein r=0.305 and 0<δ<0.01.

11. The die as set forth in claim 10, wherein δ<0.007.

12. The die as set forth in claim 10, wherein δ<0.004.
